(19) United States
(12) Patent Application Publication
(10) Pub. No.: US 2014/0120291 A1
(43) Pub. Date: May 1, 2014

(54) LAMINATED BASE MATERIAL, SUBSTRATE USING LAMINATED BASE MATERIAL, AND METHOD OF MANUFACTURING SUBSTRATE

(71) Applicant: SAMSUNG ELECTRO-MECHANICS CO., LTD., Suwon (KR)

(72) Inventors: Dae Jun KIM, Suwon (KR); Jong Sik KIM, Suwon (KR)

(73) Assignee: SAMSUNG ELECTRO-MECHANICS CO., LTD., Suwon (KR)

(21) Appl. No.: 13/761,851

(22) Filed: Feb. 7, 2013

(30) Foreign Application Priority Data
Oct. 26, 2012 (KR) 10-2012-0119643

(51) Int. Cl. C09J 7/02; H05K 3/30

(52) U.S. Cl. CPC C09J 7/0296; H05K 3/30
USPC 428/41.5; 428/41.8; 428/76; 29/832

(57) ABSTRACT

There are provided a laminated base material, a substrate using the laminated base material, and a method of manufacturing the substrate. The laminated base material includes: an insulating base; an adhesive layer formed on an upper surface of the insulating base and having adhesive properties at room temperature; and a release film formed on an upper surface of the adhesive layer.

### CROSS-REFERENCE TO RELATED APPLICATIONS

This application claims the priority of Korean Patent Application No. 10-2012-0119643 filed on Oct. 26, 2012, in the Korean Intellectual Property Office, the disclosure of which is incorporated herein by reference.

### BACKGROUND OF THE INVENTION

1. Field of the Invention

The present invention relates to a laminated base material, a substrate using the laminated base material, and a method of manufacturing the substrate.

2. Description of the Related Art

With the trend for electronic products to be lighter, thinner, and smaller, an embedded package substrate in which active elements, passive elements, and the like are embedded inside a single package has been increasingly used.

The current embedded package substrate is manufactured by mechanically processing a portion in which a die plate is to be positioned, embedding a chip, and then performing a build-up process. Then, via holes are formed in the laminate after the build-up process and circuit wirings are connected thereto.

An insulating base used in the embedded package substrate according to the related art has a single layer and has no adhesive properties at room temperature or at intermediate temperature. Therefore, when the insulating base of the related art is used, a chip may not be fixed.

Accordingly, in the manufacturing process of the embedded package substrate, adhesive tape is used to temporarily fix the chip.

However, the adhesive tape needs to be removed after a lamination process. In addition, residue may be generated in the process of removing the adhesive tape.

That is, the process of temporarily fixing the chip by using the adhesive tape, the process of removing the adhesive tape, and the like may be factors that increase the number of processes, consumable material costs, defects, and the like.

Moreover, an additional element for suppressing the generation of residue needs to be added to the process of removing the adhesive tape.

For these reasons, a method of manufacturing the embedded package substrate through a simple process without using the adhesive tape have been demanded.

### Related Art Document

(Patent Document 1) Japanese Patent Laid-Open Publication No.

### SUMMARY OF THE INVENTION

An aspect of the invention provides a laminated base material capable of omitting tape attaching and tape detaching processes.

An aspect of the invention also provides a laminated base material exhibiting adhesive properties at room temperature.

According to an aspect of the present invention, there is provided a laminated base material, including: an insulating base; an adhesive layer formed on an upper surface of the insulating base and having adhesive properties at room temperature; and a release film formed on an upper surface of the adhesive layer.

The insulating base may include epoxy.

The adhesive layer may include at least one of an acrylic based adhesive and a silicone based adhesive.

The adhesive layer may have a thickness of 10 μm or less.

The release film may include polyethylene terephthalate.

The laminated base material may further include an adhesion-enhancing layer formed between the insulating base and the adhesive layer.

The adhesion-enhancing layer may include at least one of acryl, silicone, and urethane.

The adhesion-enhancing layer may have a thickness of 1 μm or less.

According to another aspect of the present invention, there is provided a method of manufacturing a substrate, the method including: preparing a core part including a circuit pattern formed on surfaces thereof and having a cavity penetrating the upper and lower surfaces thereof; laminating a laminated base material on the lower surface of the core part so as to shield a lower side of the cavity, the laminated base material including an insulating base and an adhesive layer; embedding an electronic component in the cavity; and laminating an insulator on the upper surface of the core part.

According to another aspect of the present invention, there is provided a substrate, including: a laminated base material including an insulating base and an adhesive layer; a core part formed on an upper surface of the laminated base material and having a cavity; an electronic component formed in the cavity of the core part; and an insulator formed on upper surfaces of the electronic component and the core part.

The insulating base may include epoxy.

The adhesive layer may include at least one of an acrylic based adhesive and a silicone based adhesive.

The laminated base material may further include an adhesion-enhancing layer formed between the insulating base and the adhesive layer.

The adhesion-enhancing layer may include at least one of acryl, silicone, and urethane.

### BRIEF DESCRIPTION OF THE DRAWINGS

The above and other aspects, features and other advantages of the present invention will be more clearly understood from the following detailed description taken in conjunction with the accompanying drawings, in which:

FIGS. 1A to 1F are views showing a method of manufacturing a substrate using adhesive tape;

FIG. 2 is a cross-sectional view of a laminated base material according to an embodiment of the present invention;

FIG. 3 is a cross-sectional view of a laminated base material according to another embodiment of the present invention; and

FIGS. 4A to 4D are views showing a method of manufacturing a substrate according to an embodiment of the present invention.

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and dimensions of components may be exaggerated for clarity, and the same reference numerals will be used throughout to designate the same or like components.

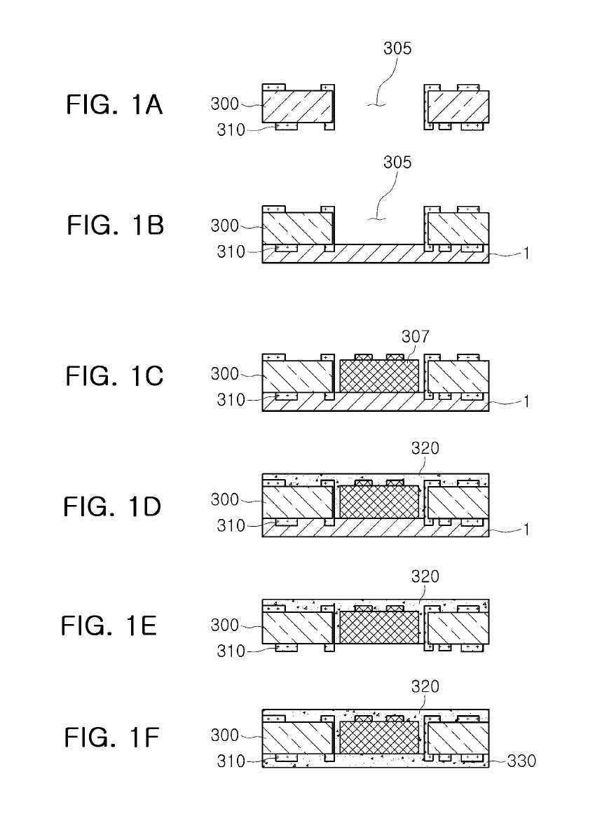

FIGS. 1A to 1F are diagrams showing a method of manufacturing a substrate using adhesive tape.

The substrate may include a core part 300 constituting a core layer, a chip 307 embedded in the substrate, and a first insulator 320 and a second insulator 330 covering both surfaces of the substrate.

The chip 307 may refer to a general electronic component such as a passive element, an active element, or the like.

In order to manufacture this substrate, the following processes are carried out.

First, as shown in FIG. 1A, a core part 300 may be prepared.

A circuit pattern 310 may be formed on the core part 300.

In addition, a cavity 305 may be formed in the core part 300 such that the cavity 305 penetrates from an upper surface of the core part 300 to a lower surface thereof. That is, the cavity 305 may be formed in the core part 300 such that the chip 307 can be embedded therein.

After the core part 300 is prepared, as shown in FIG. 1B, adhesive tape 1 may be laminated on a lower surface of the core part 300 so that a lower side of the cavity 305 is shielded.

Then, as shown in FIG. 1C, the chip 307 may be attached to the adhesive tape 1 so that the chip 307 is embedded in the cavity 305.

Then, as shown in FIG. 1D, the first insulator 320 may be laminated on the upper surface of the core part 300. The first insulator 320 may be in a semi-hardened state. When the first insulator 320 is laminated in a semi-hardened state, the first insulator 320 flows into the cavity 305.

Then, as shown in FIG. 1E, the adhesive tape 1 may be removed. In the process of removing the adhesive tape 10, residue may be generated on one surface of the core part 300 and the circuit pattern 310, to which the adhesive tape 1 has been attached.

In the case in which a vacuum/hot pressing process is performed on a substrate having a circuit pattern formed on a surface thereof or having an uneven portion formed in order to improve adhesion with a laminated material, the adhesive tape may be locally compressed and a tape base material may be deformed.

Under these conditions, excessive residue may be generated when the adhesive tape is removed.

In order to reduce generation of residue when the adhesive tape is removed, there are methods of increasing cohesion of an adhesive itself, weakening adhesion, or increasing adhesion between the adhesive and the base material.

However, these methods have limits in reducing the generation of residue of the adhesive tape.

Meanwhile, in the case in which residue remains on the uneven portion at the time of manufacturing the substrate, an additional process for removing the residue is needed. In addition, the substrate discard rate may also be increased.

Then, as shown in FIG. 1F, the second insulator 330 may be laminated on the lower surface of the core part 300. The second insulator 330 may be in a semi-hardened state like the first insulator 320.

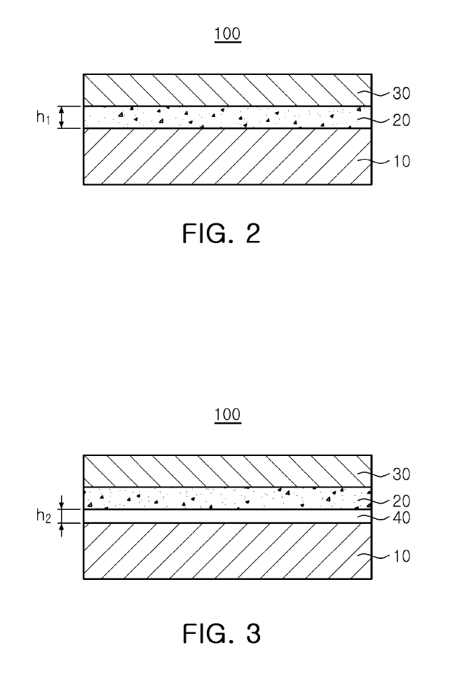

FIG. 2 is a cross-sectional view of a laminated base material according to an embodiment of the present invention.

Referring to FIG. 2, a laminated base material 100 may include an insulating base 10, an adhesive layer 20 formed on an upper surface of the insulating base 10, and a release film 30 formed on an upper surface of the adhesive layer 20.

The insulating base 10 may be a silicone or polymer complex based material having an insulating layer formed thereon. For example, the polymer complex based material may be formed of polyimide or epoxy that is often used for a printed circuit board.

In addition, the insulating base 10 may be formed of a material in which a glass fiber or the like is supplemented in an epoxy resin. In addition, the insulating base 10 may be formed of a material in which an inorganic filler such as silica or the like is blended with an epoxy resin. Here, the insulating base 10 may function as an insulator while being subjected to a heat hardening process.

The adhesive layer 20 may be formed of a material having adhesive properties at room temperature.

For example, the adhesive layer 20 may be formed of an adhesive resin, such as an acrylic resin, a silicone resin, an epoxy resin, or the like.

In addition, the adhesive layer 20 may include an acrylic based adhesive, a silicone based adhesive, a urethane based adhesive, and the like.

Here, the acrylic based adhesive may be prepared by being polymerized with an acrylic based monomer (acrylic acid alkyl ester, methacrylic acid methyl ester, or the like), a functional group containing monomer, other additives, or the like.

In addition, the silicone based adhesive may be prepared by using a polymer material composed of an organic solvent, such as monofunctional (M) unit and difunctional (D) unit silicone gums, monofunctional (M) unit and tetrafunctional (Q) unit silicone resins, toluene, xylene, or the like. The polymer material is subjected to a cross-linking reaction by peroxide or platinum catalyst, to thereby increase cohesion and be usable as an adhesive.

Meanwhile, the embodiment of the invention is not limited thereto, but any material that can have adhesive properties at room temperature may be used for the adhesive layer 20.

As such, the adhesive layer 20 is formed of a material having adhesive properties at room temperature, and thus, it can exhibit adhesive properties at room temperature.

Meanwhile, the adhesive layer may have a thickness (h1) of 10 μm or less.

In the case in which the thickness (h1) of the adhesive layer exceeds 10 μm, mechanical and electrical characteristics of the insulator may be deteriorated.

More preferably, the adhesive layer may have a thickness (h1) of 2 μm or less.

When the thickness (h1) of the adhesive layer is as thin as possible while the adhesive layer has adhesive properties, the mechanical and electrical characteristics of the insulator may be favorable.

The release film 30 is used to maintain adhesion of the adhesive layer 20. For example, the release film 30 may be attached to the adhesive layer 20 at the time of storing. In addition, in the case in which the laminated base material 100 is used, the release film 30 may be removed.

The release film may include polyethylene terephthalate.

The laminated base material 100 may be manufactured by coating the adhesive layer 20 on one surface of the release film 30 to be filmed and laminating the insulating base 10 on the filmed adhesive layer 20.

Alternatively, the laminated base material 100 may be manufactured by coating the adhesive layer 20 on one surface of the release film 30 to be filmed and coating the filmed adhesive layer 20 on one surface of the insulating base 10.

FIG. 3 is a cross-sectional view of a laminated base material according to another embodiment of the present invention.

Referring to FIG. 3, a laminated base material 100 may include an insulating base 10, an adhesive layer 20 formed on an upper surface of the insulating base 10, an adhesion-enhancing layer 40 formed on an upper surface of the adhesive layer 20, and a release film 30 formed on an upper surface of the adhesion-enhancing layer 40.

Here, the insulating base 10, the adhesive layer 20, and the release film 30 have the same configuration as that of the above-described embodiment, and thus detail descriptions thereof are omitted.

The adhesion-enhancing layer 40 may enhance adhesion between the insulating base 10 and the adhesive layer 20.

The adhesion-enhancing layer 40 may include acryl, silicone, urethane, and the like.

In addition, a material for the adhesion-enhancing layer 40 may be appropriately selected depending on the constituent materials of the insulating base 10 and the adhesive layer 20.

In the case in which the adhesive layer 20 is delaminated from the insulating base 10, the substrate manufacturing yield may be deteriorated. Therefore, the adhesion-enhancing layer 40 may contribute to an improvement in the substrate manufacturing yield.

Meanwhile, the adhesion-enhancing layer 40 may have a thickness (h2) of 1 μm or less.

In the case in which the thickness (h2) of the adhesion-enhancing layer 40 exceeds 1 μm, the adhesion-enhancing layer 40 itself may be broken, instead of enhancing adhesion, and thus performance of the adhesion-enhancing layer 40 may be deteriorated.

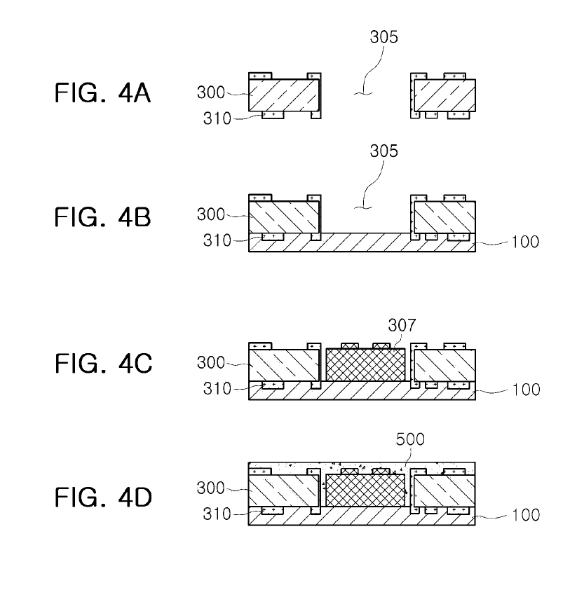

FIGS. 4A to 4D are diagrams showing a method of manufacturing a substrate according to an embodiment of the present invention.

First, as shown in FIG. 4A, a core part 300 may be prepared. A circuit pattern 310 may be formed on the core part 300.

In addition, a cavity 305 may be formed in the core part 300 such that the cavity 305 penetrates from an upper surface of the core part 300 to a lower surface thereof. That is, the cavity 305 may be formed in the core part 300 so that a chip (electronic component) 307 can be embedded. The chip 307 is embedded inside the cavity 305 through a subsequent process. The area of the cavity 305 may be wider than that of the chip 307 to form a space sufficient to embed the chip 307 therein.

After the core part 300 is prepared, a laminated base material 100 including an insulating base and an adhesive layer may be laminated on the lower surface of the core part 300 as shown in FIG. 4B, so that a lower side of the cavity 305 is shielded.

Then, as shown in FIG. 4C, the chip 307 may be attached to the laminated base material 100 so that the chip 307 is embedded in the cavity 305.

Therefore, according to the present embodiment of the invention, it is unnecessary to use separate adhesive tape for fixing the chip 307.

Here, the laminated base material 100 may exhibit adhesive properties at room temperature due to the adhesive layer.

Therefore, a process of applying high temperature and high pressure may be omitted in a process of fixing the chip 307 to the laminated base material 100.

Then, as shown in FIG. 4D, an insulator 500 may be laminated on the upper surface of the core part 300. The insulator 500 may be in a semi-hardened state. When the semi-hardened insulator 500 is laminated, the insulator 500 flows into the cavity 305.

Then, high temperature and high pressure are applied to the laminate shown in FIG. 4D to harden the semi-hardened insulator, thereby manufacturing a substrate.

In the case in which the above laminated base material is used in the manufacturing of the substrate, tape attaching and detaching processes may be omitted. Therefore, according to the embodiment of the invention, residue may not be generated at the time of detaching the adhesive layer, and thus product discard costs due to non-removed residue may be saved.

In the case in which the above laminated base material is used in the manufacturing of the substrate, an electronic component may be attached at room temperature, and thus an additional process for attaching the electronic component can be omitted.

As set forth above, according to embodiments of the present invention, there can be provided a laminated base material capable of omitting tape attaching and detaching processes.

Further, a laminated base material can exhibit adhesive properties at room temperature, resulting in simplifying a substrate manufacturing process.

While the present invention has been shown and described in connection with the embodiments, it will be apparent to those skilled in the art that modifications and variations can be made without departing from the spirit and scope of the invention as defined by the appended claims.

What is claimed is:

1. A laminated base material, comprising:
an insulating base;
an adhesive layer formed on an upper surface of the insulating base and having adhesive properties at room temperature; and
a release film formed on an upper surface of the adhesive layer.

2. The laminated base material of claim 1, wherein the insulating base includes epoxy.

3. The laminated base material of claim 1, wherein the adhesive layer includes at least one of an acrylic based adhesive and a silicone based adhesive.

4. The laminated base material of claim 1, wherein the adhesive layer has a thickness of 10 μm or less.

5. The laminated base material of claim 1, wherein the release film includes polyethylene terephthalate.

6. The laminated base material of claim 1, further comprising an adhesion-enhancing layer formed between the insulating base and the adhesive layer.

7. The laminated base material of claim 6, wherein the adhesion-enhancing layer includes at least one of acryl, silicone, and urethane.

8. The laminated base material of claim 6, wherein the adhesion-enhancing layer has a thickness of 1 μm or less.

9. A method of manufacturing a substrate, the method comprising:
preparing a core part including a circuit pattern formed on surfaces thereof and having a cavity penetrating the upper and lower surfaces thereof;
laminating a laminated base material on the lower surface of the core part so as to shield a lower side of the cavity, the laminated base material including an insulating base and an adhesive layer;
embedding an electronic component in the cavity; and
laminating an insulator on the upper surface of the core part.

10. A substrate, comprising:
a laminated base material including an insulating base and an adhesive layer;
a core part formed on an upper surface of the laminated base material and having a cavity;
an electronic component formed in the cavity of the core part; and
an insulator formed on upper surfaces of the electronic component and the core part.

11. The substrate of claim 10, wherein the insulating base includes epoxy.

12. The substrate of claim 10, wherein the adhesive layer includes at least one of an acrylic based adhesive and a silicone based adhesive.

13. The substrate of claim 10, wherein the laminated base material further includes an adhesion-enhancing layer formed between the insulating base and the adhesive layer.

14. The substrate of claim 10, wherein the adhesion-enhancing layer includes at least one of acryl, silicone, and urethane.
